(19) United States
(12) Patent Application Publication
(10) Pub. No.: US 2003/0181048 A1
(43) Pub. Date: Sep. 25, 2003

(54) STI method for semiconductor processes

(76) Inventors: Weng-Hsing Huang, Hsin-Chu City (TW); Kent Kuohua Chang, Taipei City (TW)

Correspondence Address: NAIPO (NORTH AMERICA INTERNATIONAL PATENT OFFICE), P.O. BOX 506, MERRIFIELD, VA, 22116, US

(21) Appl. No.: 10/063,131

(22) Filed: Mar. 25, 2002

(51) Int. Cl. H01L 21/311

(52) U.S. Cl. 438/694

(57) ABSTRACT

A shallow trench isolation (STI) method for use in semiconductor processes, with the method including the following steps. Having a substrate with a top surface, and forming a trench-patterned mask layer on the top surface to expose an unmasked trench region of the substrate, the mask layer including a pad oxide layer and a silicon nitride layer formed on the pad oxide layer. Etching the unmasked region of the substrate to form a trench on the substrate, depositing an HTO (high temperature oxide) film over the substrate to cover the trench and the mask layer, depositing a dielectric layer to fill the trench and to cover the HTO film, planarizing the dielectric layer to expose the silicon nitride layer, and stripping the silicon nitride.

### BACKGROUND OF INVENTION

1. Field of the Invention

The present invention relates to a shallow trench isolation (STI) method, and more particularly, to a shallow trench isolation method utilizing a high temperature oxide (HTO) film that functions as an interface reinforcement layer to protect a shallow trench edge.

2. Background of the Invention

Usually applied to semiconductor components, local oxidation of silicon (LOCOS) technology used in a conventional VLSI front end has become inefficient. Bird's beak effects in LOCOS technology has resulted in LOCOS technology not being used in high precision wafer processing. Instead, LOCOS structures have been replaced by shallow trench isolation (STI) structures, which are another form of component isolation technology. In accordance with advancements in defect detecting engineering, STI component isolation technology is found to suffer from random bit failures, which leads to an increase of current leakage in components, and decay of the STI structure. The reliability of the resulting product is thus affected.

Please refer to FIG. 1 to FIG. 7 of diagrams of a prior shallow trench isolation (STI) method. As shown in FIG. 1 , the prior art utilizes a substrate 101 to etch a trench region 102. The method to form the trench region 102 uses a mask layer 106 above a top surface of the substrate 101. The mask layer 106 is employed to define a location of the trench region 102. A dry-etching process (such as a reactive ion etching process) is then performed to etch the substrate so as to form the trench region 102. The mask layer 106 is a stacked layer, which comprises a pad oxide layer 103, a silicon nitride layer 104, and a dielectric anti-reflection coating (DARC) layer 105. SiON is generally used to form the DARC layer 105. Conventional photolithography processes and etching processes are used to define the mask layer 106.

As shown in FIG. 2, a thermal oxidization process utilizes oxygen functioning as a reaction gas, at a temperature of 900° C., to form a pad layer 107 with a thickness of 200 angstroms oxidized on a top surface of the substrate 101 within the trench region 102. The major objective in forming the pad layer 107 is to reverse lattice destruction of the substrate 101 that occurs when performing a dry-etching process to form the trench region 102. Then, a high-density plasma chemical vapor deposition (HDPCVD) process deposits an HDP oxide layer 108 to cover the mask layer 106, and fill the trench region 102.

As shown in FIG. 3, a photoresistor layer 110, also called a reverse HDP oxide mask, covers the trench region 102, and a HDP oxide layer etching process etches the HDP oxide layer 108 outside the trench region 102. The major objective of the reverse HDP oxide mask and the HDP oxide layer etching process is to prevent subsequent chemical mechanical polishing (CMP) from causing a dishing effect in the trench region 102. After stripping the photoresistor layer 110, as shown in FIG. 4, a CMP process planarizes the HDP oxide layer 108. At the end of the CMP process, the CMP process is stopped on the surface of the silicon nitride layer 104, and a remaining thickness of the silicon nitride layer 104 is left at 1300 angstroms.

As shown in FIG. 5, a STI corner rounding process utilizing a wet oxidation method, at a high temperature of 1075° C., oxidizes the substrate 101 of a STI corner region 114. As shown in FIG. 6, then an acid solution dipping process utilizes a diluted HF (DHF) solution (50:1) to clean the surface of the substrate 101 in a few minutes at room temperature, so as to remove the residual silicon oxide from the silicon nitride layer 104 and simultaneously etch the HDP oxide layer 108 to a predetermined thickness within the trench region 102.

Generally, a height of the HDP oxide layer 108 within the trench region 102 is not high enough to allow etching of the HDP oxide layer 108 for a few hundred angstroms. Unfortunately, the diluted HF (DHF) solution corrodes the HDP oxide layer 108 of the STI corner region 114 to form small voids, also called edge voids 116. This occurs because a surface binding force between the HDP oxide layer 108 and the silicon nitride layer 104 is not strong enough to resist acid solution corrosion, so producing a phenomenon of acid penetration.

As shown in FIG. 7, a thermal phosphoric acid solution is used to clean the silicon nitride layer 104. Then, a diluted HF (DHF) solution (100:1) cleans the surface of the substrate 101 in few minutes at room temperature. The previous edge voids 116 cause the acid solution to accumulate, and corrode the HDP oxide layer 108 along the edge voids 116 to form a seam defect 118. The seam defect 118 seriously affects the isolation effect of the STI, and increases current leakage.

The prior art STI method needs to repeat the acid solution dipping process a number of times in order to achieve the objectives of cleaning the surface and stripping the silicon oxide layer, affected by the acid solution corrosion. Furthermore, the oxide layer forming process, also requires the diluted HF (DHF) solution to be employed many times so enhancing the acid penetration phenomenon“s effect. The edge voids 116 and the seam defect 118 are randomly formed, so the STI method is very difficult to improve by performing extra remedial measures. Additionally, the edge voids 116 and the seam defect 118 causes abnormality in the electrical conductivity of semiconductor components. This abnormality can be seen in a double hump variation of the Id/Vg curve.

### SUMMARY OF INVENTION

It is therefore a primary objective of the present invention to provide a shallow trench isolation method utilizing a high temperature oxide (HTO) film to function as an interface reinforcement layer to protect a shallow trench edge, and thus effectively avoid an acid corroded seams problem.

The present invention discloses a shallow trench isolation (STI) method for use in semiconductor processes. This method comprises, providing a substrate with a top surface, and forming a trench-patterned mask layer on the top surface to expose an unmasked trench region of the substrate, the mask layer includes a pad oxide layer and a silicon nitride layer formed on the pad oxide layer. The unmasked region of the substrate is etched to form a trench in the substrate. A HTO (high temperature oxide) film is deposited over the substrate to cover the trench and the mask layer. A dielectric layer fills the trench and covers the HTO film. The dielectric layer is planarized to expose the silicon nitride layer and then the silicon nitride is stripped. Thereafter at least one acid solution dipping process is performed.

It is an advantage of the present invention that a high temperature oxide (HOT) film is used to avoid acid corroded seams problem and production of shallow trench seams defects.

These and other objectives and advantages of the present invention will no doubt become obvious to those of ordinary skill in the art after reading the following detailed description of the preferred embodiment that is illustrated in the various figures and drawings.

### BRIEF DESCRIPTION OF DRAWINGS

FIG. 1 to FIG. 7 are diagrams of a prior art shallow trench isolation (STI) method; and FIG. 8 to FIG. 14 are diagrams of a shallow trench isolation (STI) method according to the present invention

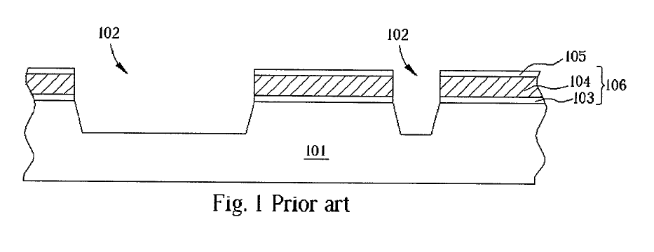

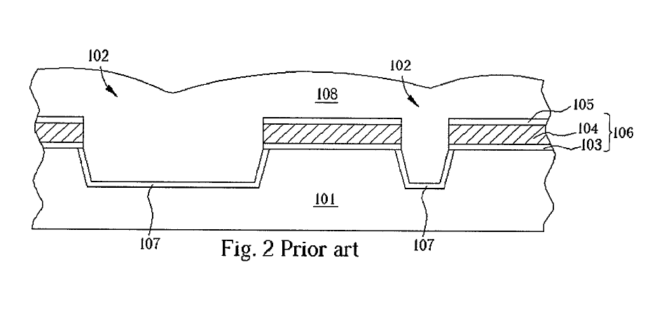

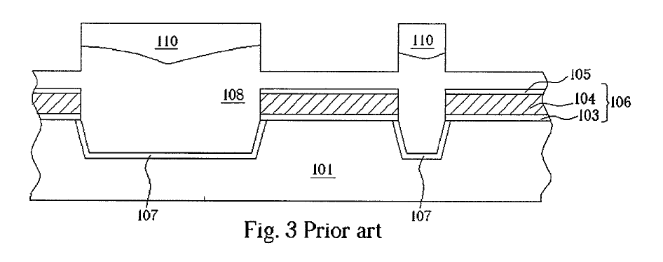

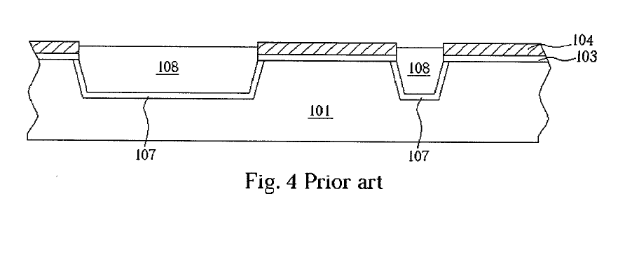

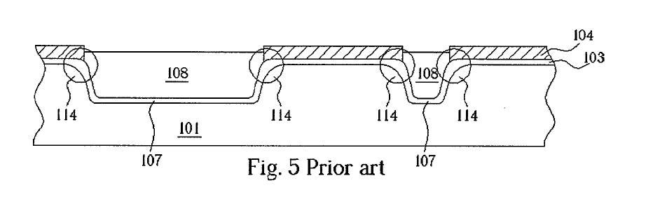

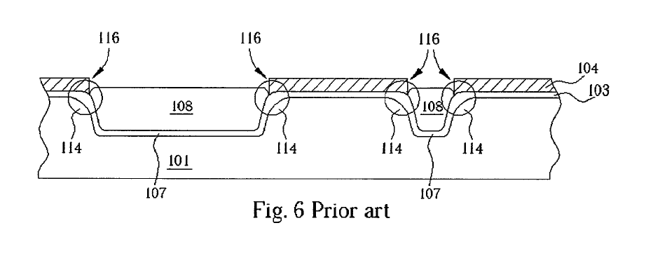

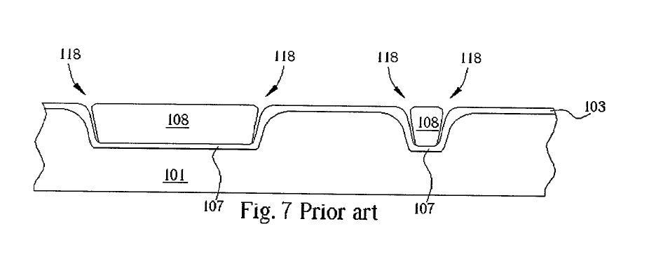

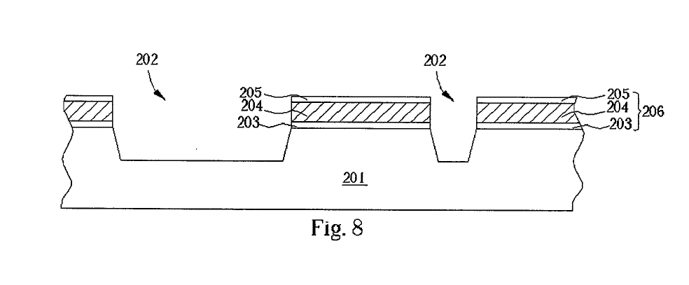

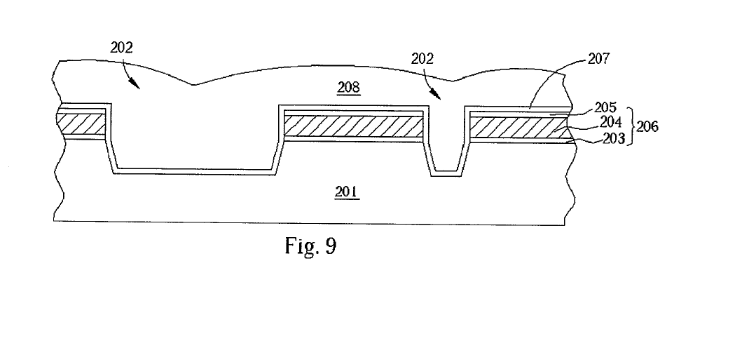

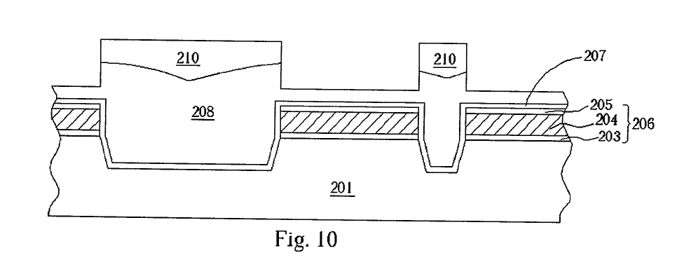

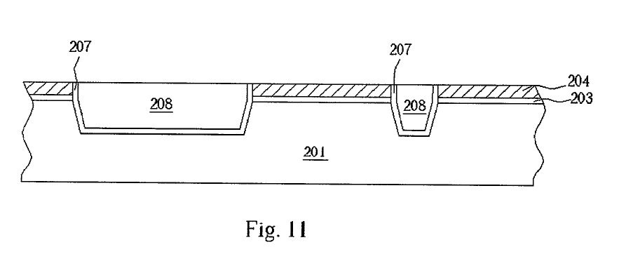

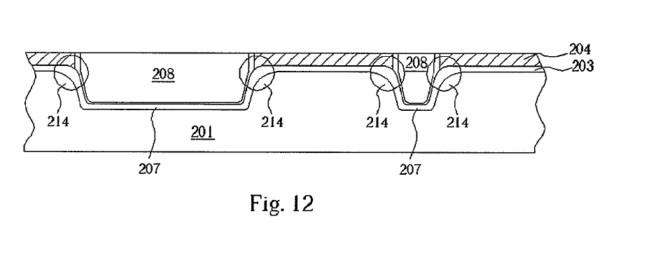

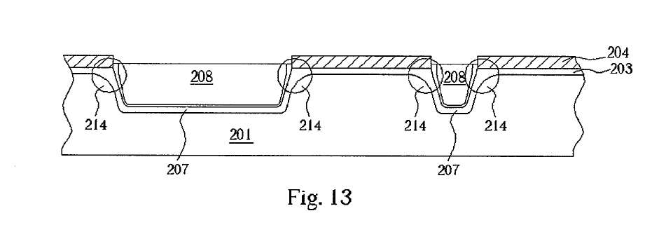

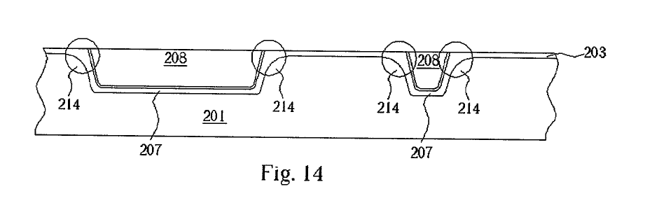

### DETAILED DESCRIPTION

Please refer to FIG. 8 to FIG. 14 of diagrams of a shallow trench isolation (STI) method according to the present invention. As shown in FIG. 8, a silicon substrate 201 is provided. In the optimal preferred embodiment, the silicon substrate 201 is a P-type doped single crystal silicon substrate with a crystal direction <100>. Nevertheless, the silicon substrate 201 can also be a silicon-on-insulator (SOI) substrate, an epitaxy silicon substrate or another silicon substrate with a different crystal structure. Then, a pad oxide layer 203 with a thickness between 100 to 300 angstroms is formed on the surface of the silicon substrate by thermal oxidization, at a temperature of 900° C. and in an oxygen/hydrogen environment. An optimal thickness of the pad oxide layer 203 is 200 angstroms.

Using a chemical vapor deposition (CVD) method, such as a low pressure chemical vapor deposition (LPCVD), a silicon nitride layer 204 with a thickness between 1800 and 2000 angstroms is deposited on the pad oxide layer. The silicon nitride layer 204 is formed, using dichlorosilane (SiH₂Cl₂) and ammonia as reaction gases, at a pressure of 0.3 Torr and a temperature of 750° C. The silicon nitride layer 204 is coated with an anti-reflection layer, that is also called a dielectric anti-reflection coating (DARC) layer 205. The DARC layer 205 is composed of SiON, with a thickness of 500 angstroms. A stacked mask 206 comprises the pad oxide layer 203, the silicon nitride layer 204 and the DARC layer 205, defining a trench isolation region.

As shown in FIG. 8, a photolithography process and an etching process are used to etch the surface of the silicon substrate 201 to form a trench region 202. The method of forming the trench region 202 uses the stacked mask 206 to define a location of the trench region 202 on the silicon substrate 201, and following that a dry-etching process (such as REI process) etches the silicon substrate 201 in order to form the trench region 202. With the trench region 202 formed the thickness of the silicon nitride layer 204 remains 1700 angstroms.

As shown in FIG. 9, an LPCVD process is performed to deposit a high temperature oxide (HTO) film 207, with a thickness of 200 angstroms, on the surface of the silicon substrate 201. The HTO film 207 covers the surface of the silicon substrate 201 and the surface of the stacked mask layer 206. Another method of forming the HTO film 207 uses dichlorosilane and nitrous oxide (N₂O) to function as reaction gases, at a pressure of 0.4 Torr and at a reaction temperature of 700° C.˜850° C. (optimal temperature is 780° C.). The flow rate of dichlorosilane is 0.12˜0.18 standard liters per minute (SLM), with an optimal flow rate of 0.15 SLM. The flow rate of N₂O is 0.2˜0.35 SLM, with an optimal flow rate of 0.3 SLM. Then, the HDPCVD process is performed to deposit a HDP oxide layer 208, with a thickness of 8000 angstroms, to fill the trench region 202 containing the HTO film 207.

As shown in FIG. 10, a photoresistor layer 210, also called a reverse HDP oxide mask, is used to cover the trench region 202, and a HDP oxide layer etching process etches the HDP oxide layer 208 outside the trench region 202. The major objective of the reverse HDP oxide mask and the HDP oxide layer etching process is to avoid the proceeding chemical mechanical polishing (CMP) process causing a dishing effect in the trench region 202. After stripping the photoresistor layer 210, as shown in FIG. 11, a CMP process planarizes the HDP oxide layer 208. The CMP process is not performed on the surface of the silicon nitride layer 204. A remaining thickness of the silicon nitride layer 204 is left at 1200˜1300 angstroms. When the CMP process is finished, the present invention HTO film 207 protects an interface between the HDP oxide layer 208 and the silicon nitride layer 204. The HDP film 207 and the silicon nitride layer 204 are tightly combined to prevent acid penetration, and further, to protect the interface between the HDP oxide layer 208 and the silicon substrate 201 so as not to produce the prior art STI seam defects.

As shown in FIG. 12, then a STI corner rounding process utilizes a wet oxidation method, under a high temperature of 1075° C., to oxidize the substrate 201 of a STI corner region 214. As shown in FIG. 13, a silicon oxide dry-etching process is then performed to etch the residual silicon oxide on the silicon nitride layer 204 and to simultaneously etch the HDP oxide layer 208 with a predetermined thickness within the trench region 202. The major objective in performing the dry-etching process is to achieve the conventional acid solution dipping process and further reduce the probability of acid penetration.

Nevertheless, in the other preferred embodiments of the present invention, the conventional acid solution dipping process can also be used. Diluted HF (DHF) solution (50:1) is used to clean the surface of the substrate 201 in few minutes, at room temperature, so as to remove the residual silicon oxide on the silicon nitride layer 204 and to simultaneously etch the HDP oxide layer 208 with a predetermined thickness within the trench region 202. The binding force between the HTO film 207, the silicon nitride layer 204 and the HDP oxide layer 208 is stronger, so that acid penetration does not occur.

As shown in FIG. 14, thermal phosphoric acid solution heated to a temperature of 160° C. is used to strip the silicon nitride layer 204. Then, diluted HF solution (100:1) cleans the surface of the substrate 201 in few minutes at room temperature. The present invention has an obvious effect of stopping acid penetration from causing the STI seam defects. The HTO film 207 functioning as an interface reinforcement layer enables the silicon nitride layer 204 and the HDP oxide layer 208 to tightly combine so as to choke the acid penetration passage.

In contrast to the prior art, the present invention has following characteristics: (1) utilizing the HTO film 207 to replace the prior art pad layer formed by a thermal oxidization process, avoiding an acid corroded seams problem that produces the STI seam defects; (2)the HTO film 207 defined as a chemical vapor deposition film, having a higher conformity than the prior art pad layer formed by the thermal oxidization process and so preventing STI holes occurring; and (3)utilizing the compact nature of the HTO film 207 to protect the STI corner region 214.

Those skilled in the art will readily observe that numerous modification and alterations of the advice may be made while retaining the teachings of the invention. Accordingly, the above disclosure should be construed as limited only by the metes and bounds of the appended claims.

What is claimed is:

1 .An shallow trench isolation (STI) method for semiconductor processes, the method comprising:
providing a substrate having a top surface;
forming a trench-patterned mask layer on the top surface exposing an unmasked trench region of the substrate, the mask layer comprising a pad oxide layer, and a silicon nitride layer formed on the pad oxide layer;
etching the unmasked region of the substrate to form a trench in the substrate;
depositing a high temperature oxide (HTO) film over the substrate, the HTO film covering the trench and the mask layer;
depositing a dielectric layer that fills the trench and covers the HTO film;
planarizing the dielectric layer to expose the silicon nitride layer; and
stripping the silicon nitride layer;
wherein the HTO film reinforces an interface between the dielectric layer and the substrate to prevent acid penetration and acid-corroded seams forming during the acid solution dipping process.

2. The method of claim 1 wherein the HTO film is formed by a low-pressure chemical vapor deposition (LPCVD) process, the LPCVD process utilizing a SiH₂ Cl₂/N₂O gas system, a pressure of 0.4 Torr, and a temperature between 700 ° C. and 850° C.

3. The method of claim 1 wherein the HTO film has a thickness between 50 and 250 angstroms.

4. The method of claim 1 wherein the dielectric layer is a high density plasma (HDP) oxide layer.

5. The method of claim 1 wherein before stripping the silicon nitride layer, the method further comprises performing a silicon oxide etching process to remove residual silicon oxide from the silicon nitride layer and to simultaneously etch the dielectric layer in the trench.

6. The method of claim 1 wherein the acid solution dipping process uses a diluted HF (DHF) solution.

7. The method of claim 1 wherein a 160 ° C. phosphoric acid solution is used to strip the silicon nitride layer.
